(19) United States
(12) Patent Application Publication
(10) Pub. No.: US 2004/0099897 A1
(43) Pub. Date: May 27, 2004

(54) Semiconductor device and method for fabricating the same

(76) Inventors: Makoto Tsutsue, Shiga (JP); Toshiki Yabu, Osaka (JP); Yoshiaki Kato, Hyogo (JP); Tetsuya Ueda, Osaka (JP); Satoshi Seo, Kyoto (JP)

Correspondence Address: MCDERMOTT, WILL & EMERY, 600 13th Street, N.W., Washington, DC, 20005-3096, US

(21) Appl. No.: 10/674,068

(22) Filed: Sep. 30, 2003

(30) Foreign Application Priority Data
Sep. 30, 2002 (JP) 2002-286767

(51) Int. Cl. H01L 27/108

(52) U.S. Cl. 257/303

(57) ABSTRACT

An inventive semiconductor device includes: an interlevel dielectric film 204 provided on a semiconductor substrate 101; and interconnects 208a and 208c buried in the interlevel dielectric film 204 and electrically connected to the semiconductor substrate 101. An MIM capacitor 201 includes: first and second electrodes 208b and 214b each made of a metal; and a capacitive insulating film 210 of a dielectric. The first electrode 208b is buried in the interlevel dielectric film 204. The capacitive insulating film 210 is provided on the first electrode 208b. The second electrode 214b is a metal layer provided to face the first electrode 208b with the capacitive insulating film 210 interposed therebetween.

### BACKGROUND OF THE INVENTION

The present invention relates to semiconductor devices including metal-insulator-metal (MIM) capacitors and methods for fabricating the same.

Recently, incorporation of an analog device and a CMOS logic device into one chip has been developed. In particular, the CMOS logic device has been downsized year by year. When the gate length of an MOS transistor comes to less than 0.1 μm, copper (Cu), which is a low resistivity material, is used as an interconnect material and a damascene process is used as a method for forming interconnection in order to reduce the interconnect resistance. On the other hand, with the progress of miniaturization, transistors have been more and more densely integrated and the number of interconnect layers in a CMOS logic device tends to increase. That is to say, with miniaturization of a semiconductor device and increase in the number of interconnect layers, it is more and more significant how to form a large-capacitance capacitor in an analog device without preventing high degree of integration in the device.

With respect to a capacitor in an analog device, a method adopting a comb-like electrode to solve problems such as dishing which occurs in a damascene process for forming an MIM capacitor electrode is proposed in Japanese Laid-Open Publication No. 2001-237375, for example.

In Japanese Laid-Open Publication No. 2002-33453, a thin-film capacitor 414 provided on the surface of four interconnect layers formed on a silicon substrate 401a is disclosed as shown in FIG. 7. A plurality of microfabricated devices 402 are formed on the silicon substrate 401a. The four interconnect layers include respective interlevel dielectric films 403a, 403b, 403c and 403d and respective contacts 405a, 405b, 405c and 405d. The three upper layers further include interconnects 404a, 404b, 404c, 404d and 404e. The thin-film capacitor 414 is made up of a lower electrode 406 of Pt formed on the surface of the uppermost interconnect layer, a dielectric 407 of SrTiO₃ formed on the lower electrode 406, and an upper electrode 408 of Pt formed on the dielectric 407. The lower electrode 406 is connected to a ground line 404e in the uppermost interconnect layer. The upper electrode 408 is connected to a power source line 404d.

However, if the comb-like electrode disclosed in Japanese Laid-Open Publication No. 2001-237375 is used, a large region is damaged during processing with respect to the electrode area. In addition, as compared to a rectangular electrode, the comb-like electrode has a small capacitance with respect to the area of the electrode so that it is difficult to form a large-capacitance capacitor. Furthermore, there arises a problem of variation in capacitance due to variation in the size of the processed teeth of the comb.

Since the process size is smaller and patterns are more densely arranged at a lower level of a multilevel interconnect structure, it is very difficult to form a large-capacitance capacitor having a large area in a layer at a lower level.

In the structure recited in Japanese Laid-Open Publication No. 2002-33453, though this problem is solved, all the processes necessary for forming a capacitor should be added after the formation of the semiconductor substrate and the multilevel interconnect. As a result, the structure has a problem of a largely increased number of processes.

### SUMMARY OF THE INVENTION

It is therefore an object of the present invention to form a highly reliable MIM capacitor with a large capacitance by a simple fabrication method in a semiconductor device including the MIM capacitor.

An inventive semiconductor device is a semiconductor device including an MIM capacitor and further includes: a semiconductor substrate; an interlevel dielectric film provided on the semiconductor substrate; and an interconnect buried in the interlevel dielectric film and electrically connected to the semiconductor substrate, wherein the MIM capacitor includes a first electrode of a metal, a second electrode of a metal and a capacitive insulating film of a dielectric, the first electrode is buried in the interlevel dielectric film, the capacitive insulating film is provided on the first electrode, and the second electrode is a metal layer provided to face the first electrode with the capacitive insulating film interposed therebetween.

In one preferred aspect, a pad electrode is provided and exposed on part of the interconnect, and the pad electrode and the second electrode are made of the metal layer.

In another preferred aspect, a pad electrode is provided and exposed on part of the interconnect, a connecting line for electrically connecting another part of the interconnect to the second electrode is provided on the second electrode, and the pad electrode and the connecting line are made of an identical metal film.

The capacitive insulating film is preferably a film having a function of preventing diffusion of the metal constituting at least one of the first and second electrodes.

In still another preferred aspect, the capacitive insulating film is a film made of silicon nitride.

An inventive method for fabricating a semiconductor device includes the steps of: a) forming an interlevel dielectric film on a semiconductor substrate; b) forming a plurality of grooves and a plurality of via holes in the interlevel dielectric film; c) filling a metal in the grooves and the via holes, thereby forming a first electrode for an MIM capacitor and an interconnect electrically connected to the semiconductor substrate; d) forming a capacitive insulating film of a dielectric on the first electrode; and e) providing a metal layer on the capacitive insulating film, thereby forming a second electrode for the MIM capacitor.

In one preferred aspect, in the step e), a pad electrode is also formed out of the metal layer on part of the interconnect.

In another preferred aspect, the step d) is the step of forming the capacitive insulating film on surfaces of the first electrode, the interconnect and an exposed part of the interlevel dielectric film, the step e) is the step of providing the metal layer on the capacitive insulating film and then etching the metal layer, thereby forming the second electrode, and the method further includes the steps of: removing part of the capacitive insulating film after the step e) has been performed; and forming a connecting line for connecting the second electrode to part of the interconnect and a pad electrode connected to another part of the interconnect.

The capacitive insulating film is preferably a film having a function of preventing diffusion of the metal constituting at least one of the first and second electrodes.

In still another preferred aspect, the capacitive insulating film is a film made of silicon nitride.

### BRIEF DESCRIPTION OF THE DRAWINGS

FIG. 1 is a cross-sectional view showing a semiconductor device according a first embodiment of the present invention.

FIGS. 2A through 2D are cross-sectional views showing respective process steps for fabricating the semiconductor device of the first embodiment.

FIG. 3 is a cross-sectional view showing a semiconductor device according a second embodiment of the present invention.

FIGS. 4A through 4D are cross-sectional views showing respective process steps for fabricating the semiconductor device of the second embodiment.

FIG. 5 is a flowchart showing process steps for fabricating the semiconductor device of the first embodiment.

FIG. 6 is a flowchart showing process steps for fabricating the semiconductor device of the second embodiment.

FIG. 7 is a cross-sectional view showing a prior art semiconductor device.

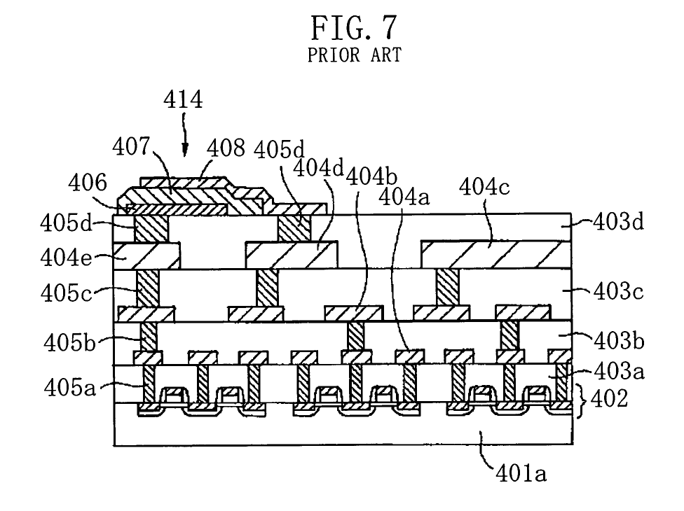

### DESCRIPTION OF THE PREFERRED EMBODIMENTS

An inventive semiconductor device includes an MIM capacitor and further includes: a semiconductor substrate; an interlevel dielectric film provided on the semiconductor substrate; and an interconnect buried in the interlevel dielectric film and electrically connected to the semiconductor substrate. The MIM capacitor includes a first electrode of a metal, a second electrode of a metal and a capacitive insulating film of a dielectric, the first electrode is buried in the interlevel dielectric film, the capacitive insulating film is provided on the first electrode, and the second electrode is a metal layer provided to face the first electrode with the capacitive insulating film interposed therebetween. Accordingly, the interconnect in the interconnect layer provided on the semiconductor substrate and the first electrode of the MIM capacitor are formed at the same time (i.e., in the same step), so that the number of process steps for fabricating a semiconductor device is reduced, resulting in reduction of the fabrication cost. The MIM capacitor is a capacitor having a metal-insulator-metal configuration.

In one aspect, a pad electrode is provided and exposed on part of the interconnect, and the pad electrode and the second electrode are made of the metal layer. Accordingly, the MIM capacitor is formed in the uppermost layer of the multilevel interconnection. In the uppermost layer of the multilevel interconnection, interconnect patterns are more sparsely arranged than in lower layers, so that a capacitor electrode having a large area can be easily formed, thus increasing the capacitance. In addition, the pad electrode and the second electrode of the MIM capacitor are formed at the same time, so that the number of process steps for fabricating a semiconductor device is reduced, resulting in reduction of the fabrication cost. The pad electrode is an electrode for connection provided in the semiconductor device to connect the semiconductor device to an external element or to a wiring board and is a portion for inputting/outputting a signal or receiving power supply current. The pad electrode is generally made of a metal (e.g., aluminum) exposed on the surface of the semiconductor device.

The capacitive insulating film is preferably a film having a function of preventing diffusion of the metal constituting at least one of the first and second electrodes. For example, in the case where one of the electrodes is made of Cu, if the capacitive insulating film is made of at least one material selected from the group consisting of SiN, SiON, SiC and SiOC, the capacitive insulating film also has a function of preventing Cu from diffusing, so that it is unnecessary to form an additional Cu-diffusion preventing film. As a result, increase in the number of process steps is suppressed, thus reducing the fabrication cost. In addition, a SiN film is generally formed as a protection film in the uppermost surface of a semiconductor device in order to prevent the surface of the semiconductor device from being scratched and to prevent the entry of water from outside. Accordingly, the capacitive insulating film is more preferably made of SiN. Then, the entry of water from outside is prevented and the same materials and apparatus in known fabricating processes can be used, resulting in suppressing increase in the fabrication cost.

Hereinafter, embodiments of the present invention will be described in detail with reference to the drawings. In the drawings, components having substantially the same function are identified by the same reference numeral for the sake of simplicity.

Embodiment 1

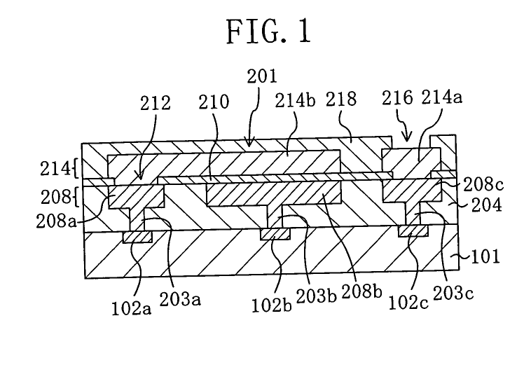

A first embodiment of the present invention will be described with reference to FIGS. 1, 2A through 2D and 5.

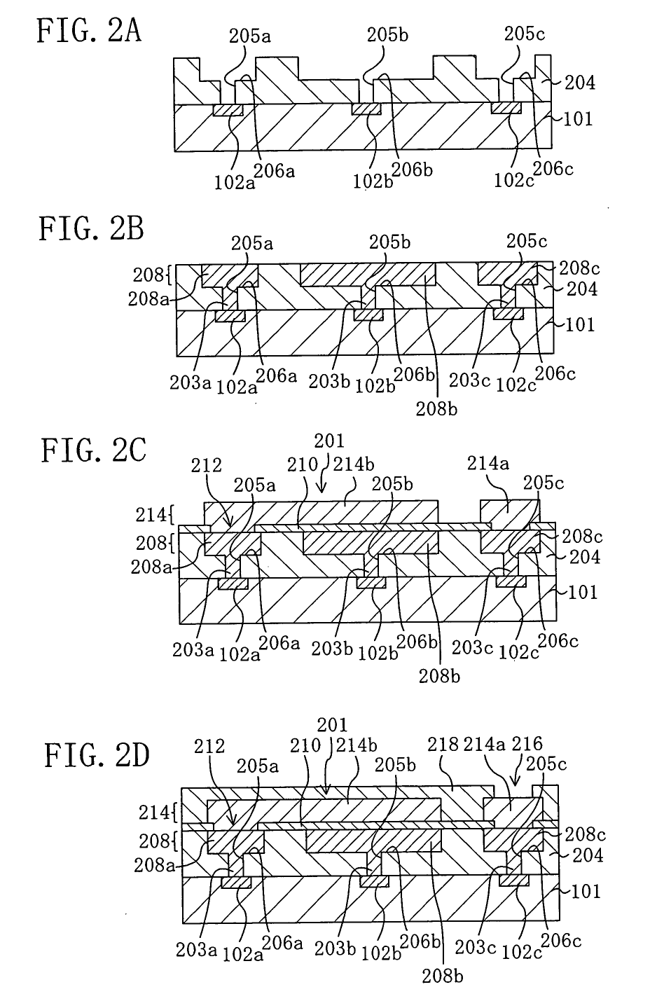

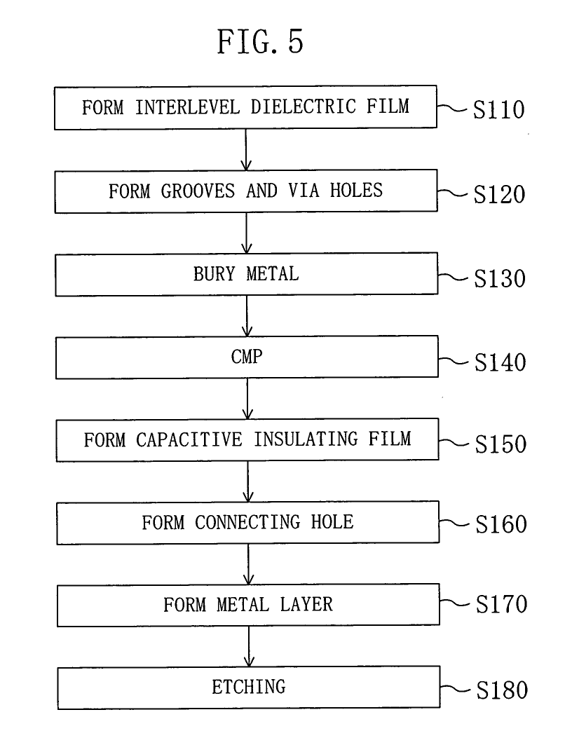

FIG. 1 is a cross-sectional view schematically showing a semiconductor device according this embodiment. FIGS. 2A through 2D are schematic cross-sectional views showing respective process steps for fabricating the semiconductor device of this embodiment. FIG. 5 is a flowchart showing process steps for fabricating the semiconductor device of this embodiment.

As shown in FIG. 1, the semiconductor device of this embodiment includes: a semiconductor substrate 101; an interlevel dielectric film 204 provided on the substrate 101; and an MIM capacitor 201 part of which is buried in the interlevel dielectric film 204 and the other part of which is provided on the interlevel dielectric film 204. The semiconductor substrate 101 is, for example, a silicon substrate in which components such as a transistor (not shown), another electric element (not shown) and interconnects 102a, 102b and 102c are formed or the silicon substrate further provided with at least one interconnect layer (interlevel dielectric film with metal interconnects) thereon. Interconnects 208a and 208c and a first electrode 208b are made of copper and buried in the interlevel dielectric film 204. The interconnects 208a and 208c and the first electrode 208b are electrically connected to respective interconnects 102a, 102c and 102b in the semiconductor substrate 101 by way of vias 203a, 203c and 203b. The MIM capacitor 201 is made up of a first electrode 208b buried in the interlevel dielectric film 204, a capacitive insulating film 210 provided on the first electrode 208b and a second electrode 214b of aluminum provided on the capacitive insulating film 210. The second electrode 214b is connected to the interconnect 208a via aluminum filling in a connecting hole 212 provided in the capacitive insulating film 210. A pad electrode 214a made of a metal layer 214 which is also used for the second electrode 214b is formed on the interconnect 208c. A protection film 218 of SiN is formed on the entire surface of the uppermost layer except for the pad electrode 214a. The pad electrode 214a is exposed in an opening 216 provided in he protection film 218.

In the semiconductor device thus configured, the MIM capacitor 201 is formed in a metal layer in which the interconnects 208a and 208c and the pad electrode 214a are also formed. Accordingly, the MIM capacitor 201 having a large area can be formed with a small number of process steps.

Now, a method for fabricating a semiconductor device of this embodiment will be described with reference to FIGS. 2A through 2D and FIG. 5.

As shown in FIG. 2A, an interlevel dielectric film 204 is formed on a semiconductor substrate 101 (S110, step a). Then, interconnect grooves 206a and 206c, a first electrode groove 206b and via holes 205a, 205c and 205b are formed in the interlevel dielectric film 204 (S120, step b).

Next, as shown in FIG. 2B, a Cu layer 208 is deposited by an electrolytic plating process to fill the interconnect grooves 206a and 206c, the first electrode groove 206b and the via holes 205a, 205c and 205b (S130). Thereafter, the Cu layer 208 is polished by a chemical mechanical polishing (CMP) process (S140), thereby forming interconnects 208a and 208c buried in the interlevel dielectric film 204, a first electrode 208b as a lower electrode of an MIM capacitor 201, and vias 203a, 203c and 203b. Steps S130 and S140 together constitute step c.

Subsequently, as shown in FIG. 2C, a capacitive insulating film 210 of SiN having functions as a capacitive film as a dielectric for the MIM capacitor 201 as well as a Cu-diffusion preventing film is formed by a CVD process on the surfaces of the interlevel dielectric film 204, the interconnects 208a and 208c and the first electrode 208b which are exposed after the CMP process (S140) (S150, step d). Then, a connecting hole 212 is formed by dry etching in the capacitive insulating film 210 formed on the interconnects 208a and 208c (S160).

Thereafter, a metal layer 214 of aluminum is formed by a sputtering process on the capacitive insulating film 210 (S170). Then, dry etching is performed (S180), thereby forming a second electrode 214b facing the first electrode 208b with the capacitive insulating film 210 interposed therebetween. (step e). The second electrode 214b is electrically connected to the interconnect 208a at a lower level via aluminum filling the connecting hole 212. Dry etching is performed (S180) simultaneously with the formation of the second electrode 214b, thereby forming a pad electrode 214a.

Then, as shown in FIG. 2D, a protection film 218 of SiN is formed on the second electrode 214b and the pad electrode 214a, and an opening 216 is formed in part of the protection film 218 located on the pad electrode 214a.

With the method for fabricating the semiconductor device as described above, the MIM capacitor 201 can be formed simultaneously with the formation of the interconnects 208a and 208c and the pad electrode 214a (steps c and e), so that the necessity for adding process steps for the formation of the MIM capacitor 201 can be reduced. In addition, the capacitive insulating film 210 is made of SiN, so that it is unnecessary to form an additional Cu-diffusion preventing film, thus reducing the number of process steps. Furthermore, SiN exhibits excellent moisture resistance, unlike Ta₂O₅ that is generally used for a capacitive insulating film of an MIM capacitor. Accordingly, the capacitive insulating film 210 also serves as a protection film at an upper level of the semiconductor device. In general, a SiN film is formed as a protection film in the surface of the semiconductor device. Accordingly, if a capacitive insulating film is made of SiN, conventional materials and conventional apparatus can be used without change, resulting in suppressing increase in fabrication cost.

Embodiment 2

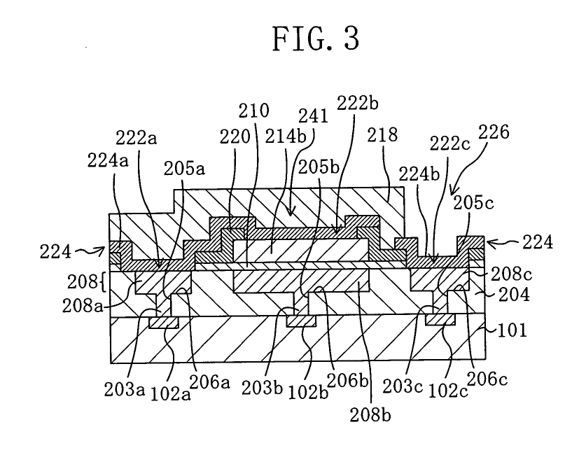

A second embodiment of the present invention will be described with reference to FIGS. 3, 4A through 4D and 6. In this embodiment, the interlevel dielectric film 204 and portions at lower levels than the interlevel dielectric film 204 are substantially the same as those in the first embodiment, and the descriptions thereof will be partly omitted herein.

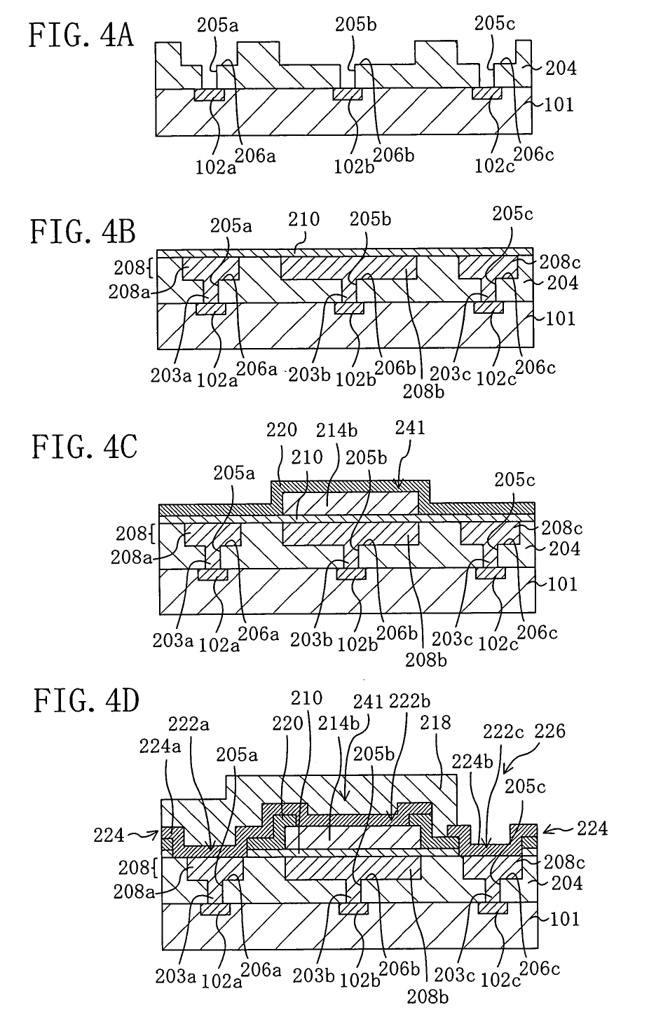

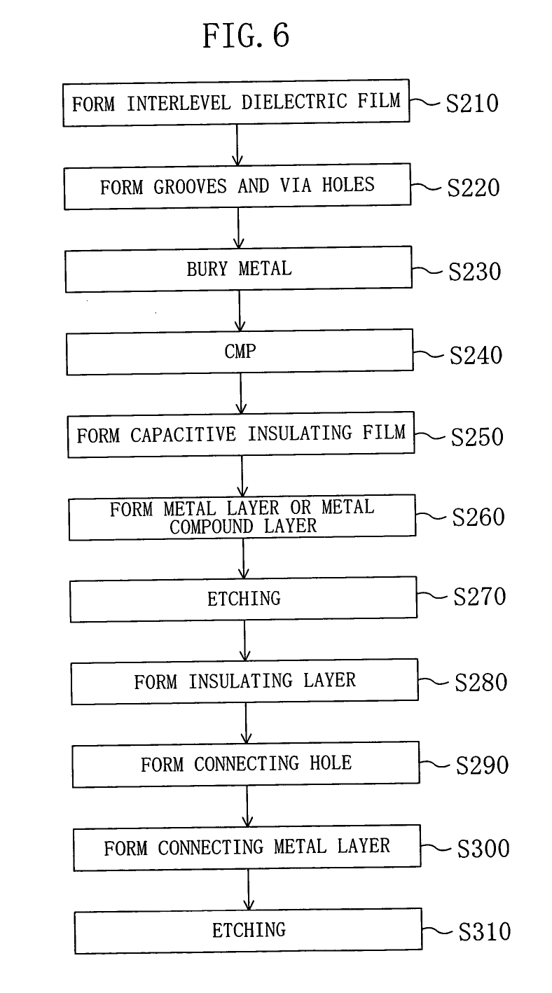

FIG. 3 is a cross-sectional view schematically showing a semiconductor device according this embodiment. FIGS. 4A through 4D are schematic cross-sectional views showing respective process steps for fabricating the semiconductor device of this embodiment. FIG. 6 is a flowchart showing process steps for fabricating the semiconductor device of this embodiment.

As shown in FIG. 3, the semiconductor device of this embodiment includes: a semiconductor substrate 101; an interlevel dielectric film 204 provided on the substrate 101; and an MIM capacitor 241 part of which is buried in the interlevel dielectric film 204 and the other part of which is provided on the interlevel dielectric film 204. Interconnects 208a and 208c and a first electrode 208b are made of copper, buried in the interlevel dielectric film 204 and electrically connected to the semiconductor substrate 101 by way of vias 203a, 203c and 203b, respectively. The MIM capacitor 241 is made up of a first electrode 208b buried in the interlevel dielectric film 204, a capacitive insulating film 210 provided on the first electrode 208b and a second electrode 214b of aluminum provided on the capacitive insulating film 210. The second electrode 214b is connected to the interconnect 208a via a connecting line 224a provided on the second electrode 214b. The connecting line 224a is connected to the interconnect 208a in part of a connecting hole 222a provided in the capacitive insulating film 210. A pad electrode 224b made of a metal layer 224 which is also used for the connecting line 224a is formed on the interconnect 208c. A protection film 218 is formed on the entire surface of the substrate except for the pad electrode 224b. The pad electrode 224b is exposed in an opening 226 provided in the protection film 218.

In the semiconductor device of this embodiment, the first electrode 208b of the MIM capacitor 241 is also formed in the metal layer in which the interconnect 208a and 208c are formed. Accordingly, the MIM capacitor 201 having a large area can be formed with a small number of process steps.

Now, a method for fabricating the semiconductor device of this embodiment will be described with reference to FIGS. 4A through 4D and FIG. 6.

As shown in FIG. 4A, an interlevel dielectric film 204 is formed on a semiconductor substrate 101 (S210, step a). Then, interconnect grooves 206a and 206c, a first electrode groove 206b and via holes 205a, 205c and 205b are formed in the interlevel dielectric film 204 (S220, step b).

Next, as shown in FIG. 4B, a Cu layer 208 is deposited by an electrolytic plating process to fill the interconnect grooves 206a and 206c, the first electrode groove 206b and the via holes 205a, 205c and 205b (S230). Thereafter, the Cu layer 208 is polished by a chemical mechanical polishing (CMP) process (S240), thereby forming interconnects 208a and 208c buried in the interlevel dielectric film 204, a first electrode 208b as a lower electrode of an MIM capacitor 241, and vias 203a, 203c and 203b. Steps S230 and S240 together constitute step c.

Subsequently, a capacitive insulating film 210 of SiN having functions as a capacitive film as a dielectric for the MIM capacitor 241 as well as a Cu-diffusion preventing film is formed by a CVD process on the surfaces of the interlevel dielectric film 204, the interconnects 208a and 208c and the first electrode 208b which are exposed after the CMP process (S240) (S250, step d).

Then, as shown in FIG. 4C, an aluminum metal layer is formed by a sputtering process on the capacitive insulating film 210 (S260). Then, a second electrode 214b as an upper electrode is formed by dry etching to face the first electrode 208b with the capacitive insulating film 210 interposed therebetween (S270, step e). Subsequently, an insulating film 220 is formed thereon (S280).

Then, as shown in FIG. 4D, the insulating film 220 and the capacitive insulating film 210 are dry etched, thereby forming openings (connecting holes) 222a, 222b and 222c (S290). Thereafter, a metal film (connecting metal layer) 224 of aluminum is formed so as to electrically connect the electrode 214b to the interconnect 208a (S300). Then, the metal film 224 is etched, thereby forming a connecting line 224a and a pad electrode 224b (S310). The pad electrode 224b is electrically connected to the interconnect 208c in the opening 222c. Thereafter, a protection film 218 of SiN is formed on the semiconductor substrate, and an opening 226 is formed in part of the protection film 218 located on the pad electrode 224b, thereby exposing the pad electrode 224b.

With the method for fabricating the semiconductor device as described above, the MIM capacitor 241 is formed simultaneously with the formation of the interconnects 208a and 208c and the pad electrode 224b in processes from the formation of the interconnects 208a and 208c to the formation of the pad electrode 224b (steps c and e), so that a smaller number of process steps are added to form the MIM capacitor 241. In addition, the capacitive insulating film 210 is made of SiN, so that it is unnecessary to form an additional Cu-diffusion preventing film, thus reducing the number of process steps. Furthermore, SiN exhibits excellent moisture resistance, unlike Ta₂O₅ that is generally used for a capacitive insulating film of an MIM capacitor. Accordingly, the capacitive insulating film 210 also serves as a protection film at an upper level of the semiconductor device. In general, a SiN film is formed as a protection film in the surface of the semiconductor device. Accordingly, if a capacitive insulating film is made of SiN, conventional materials and conventional apparatus can be used without change, resulting in suppressing increase in fabrication cost.

In addition, in the semiconductor device of this embodiment, immediately after the formation of a capacitive insulating film 210, a metal film (metal film constituting the second electrode 214b) is formed on the as-formed capacitive insulating film 210. Accordingly, the capacitive insulating film 210 is not affected by etching or a lithographic process. Specifically, in forming openings 222a and 222c in the capacitive insulating film 210 to establish connections between the second electrode 214b and the interconnect 208a and between the pad electrode 224b and the interconnect 208c, part of the capacitive insulating film 210 sandwiched between the first and second electrodes 208b and 214b is not affected by etching or a lithographic process. Accordingly, the thickness and film properties of the resultant capacitive insulating film 210 are maintained without change, so that the MIM capacitor 241 is formed to have a capacitance and characteristics as designed. In addition, variations in capacitance and characteristics of the MIM capacitor 241 can be suppressed.

In step S260, the metal layer or metal compound layer formed on the capacitive insulating film 210 may be made of Ti, TiN or Ti/TiN. Accordingly, the second electrode 214 may be an electrode also made of Ti, TiN or Ti/TiN.

The foregoing embodiments are examples and the present invention is not limited to these examples. The interconnects and the electrodes of the MIM capacitor may be made of a metal such as silver or an alloy other than Cu and aluminum. The interlevel dielectric film and the insulating film may be made of any material such as silicon oxide, silicon oxide containing fluorine. The structure of the MIM capacitor is not specifically limited so long as the MIM capacitor functions as a capacitor.

As described above, in the inventive semiconductor device including an MIM capacitor made of a stack of a metal electrode, an insulating film and a metal electrode and an inventive method for fabricating the semiconductor device, a capacitor electrode is formed out of an interconnect layer located at an upper level in which patterns are arranged more sparsely than in lower levels, so that the electrode area of the MIM capacitor can be increased as compared to the case of an MIM capacitor formed in a lower-level interconnect layer. In addition, the capacitor electrode and the interconnects are formed out of an identical metal layer at the same time, so that fabrication process steps can be shared. As a result, a smaller number of additional process steps are needed to form the capacitor, as compared to the case where a MIM capacitor electrode is formed in the uppermost layer.

What is claimed is:

1. A semiconductor device including an MIM capacitor, the semiconductor device comprising:
a semiconductor substrate;
an interlevel dielectric film provided on the semiconductor substrate; and
an interconnect buried in the interlevel dielectric film and electrically connected to the semiconductor substrate,
wherein the MIM capacitor includes a first electrode of a metal, a second electrode of a metal and a capacitive insulating film of a dielectric,
the first electrode is buried in the interlevel dielectric film,
the capacitive insulating film is provided on the first electrode, and
the second electrode is a metal layer provided to face the first electrode with the capacitive insulating film interposed therebetween.

2. The semiconductor device of claim 1, wherein a pad electrode is provided and exposed on part of the interconnect, and
the pad electrode and the second electrode are made of the metal layer.

3. The semiconductor device of claim 1, wherein a pad electrode is provided and exposed on part of the interconnect,
a connecting line for electrically connecting another part of the interconnect to the second electrode is provided on the second electrode, and
the pad electrode and the connecting line are made of an identical metal film.

4. The semiconductor device of claim 1, wherein the capacitive insulating film is a film having a function of preventing diffusion of the metal constituting at least one of the first and second electrodes.

5. The semiconductor device of claim 1, wherein the capacitive insulating film is a film made of silicon nitride.

6. A method for fabricating a semiconductor device, the method comprising the steps of
a) forming an interlevel dielectric film on a semiconductor substrate;
b) forming a plurality of grooves and a plurality of via holes in the interlevel dielectric film;
c) filling a metal in the grooves and the via holes, thereby forming a first electrode for an MIM capacitor and an interconnect electrically connected to the semiconductor substrate;
d) forming a capacitive insulating film of a dielectric on the first electrode; and
e) providing a metal layer on the capacitive insulating film, thereby forming a second electrode for the MIM capacitor.

7. The method of claim 6, wherein in the step e), a pad electrode is also formed out of the metal layer on part of the interconnect.

8. The method of claim 6, wherein the step d) is the step of forming the capacitive insulating film on surfaces of the first electrode, the interconnect and an exposed part of the interlevel dielectric film,
the step e) is the step of providing the metal layer on the capacitive insulating film and then etching the metal layer, thereby forming the second electrode, and
the method further includes the steps of
removing part of the capacitive insulating film after the step e) has been performed; and
forming a connecting line for connecting the second electrode to part of the interconnect and a pad electrode connected to another part of the interconnect.

9. The method of claim 6, wherein the capacitive insulating film is a film having a function of preventing diffusion of the metal constituting at least one of the first and second electrodes.

10. The method of claim 6, wherein the capacitive insulating film is a film made of silicon nitride.
